(19) United States
(12) Patent Application Publication
(10) Pub. No.: US 2014/0340974 A1
(43) Pub. Date: Nov. 20, 2014

(54) APPARATUS AND METHOD FOR WRITING DATA INTO STORAGE OF ELECTRONIC DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: YA-GUO WANG, Shenzhen (CN); CHUN-CHING CHEN, New Taipei (TW)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 14/260,528

(22) Filed: Apr. 24, 2014

(30) Foreign Application Priority Data
May 16, 2013 (CN) 201310181300X

(51) Int. Cl. G11C 7/22; G11C 16/34

(52) U.S. Cl. CPC G11C 7/22; G11C 16/34
USPC 365/191

(57) ABSTRACT

An electronic device includes a storage and a processor. When the processor performs a data transmission process performed by the processor to transmit data to the storage, a time period duration of writing data into the storage is timed. An Acknowledge (ACK) signal indicating the data is successfully written into the storage is detected. If the ACK signal is not detected and the time period duration exceeds a predetermined time period, the processor restarts the data transmission process to re-transmit the data to the storage, to avoid system crash.

### FIELD

Embodiments of the present disclosure relate generally to data transmission technologies of electronic devices, and particularly to a method for writing data into a storage of an electronic device.

### BACKGROUND

Electronic devices, such as tablet computers and portable devices, include at least one processor such as CPU and at least one storage such as read only memory (ROM), erasable programmable read only memory (EPROM), and electrically erasable programmable read only memory (EEPROM). The processor typically writes data into the storage to perform various tasks. When the data is successfully written into the storage, the storage will return an Acknowledge (ACK) signal to the processor to indicate to the processor to perform a next task. However, if malfunction such as data error happens during the data writing process, the processor cannot receive the ACK signal from the storage, which may cause the processor to not perform the next task and cause the electronic device to crash. Therefore, there is room for improvement in the art.

### BRIEF DESCRIPTION OF THE DRAWINGS

FIG. 1 is a block diagram of an electronic device including a data writing unit.

FIG. 2 is a flowchart of one embodiment of a data writing method implemented by the data writing unit of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”. The reference “a plurality of” means “at least two”.

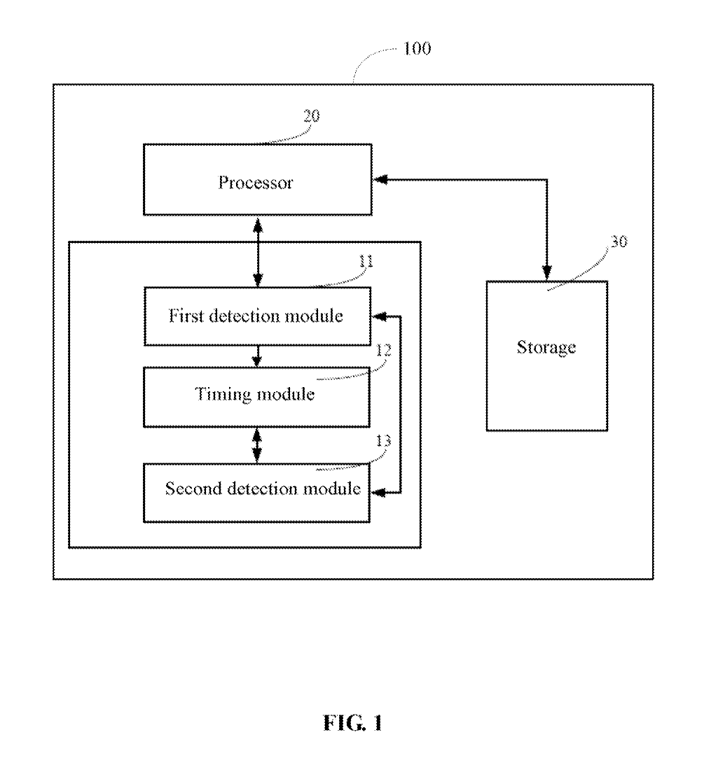

FIG. 1 illustrates a block diagram of an electronic device 100. The electronic device 100 can include a data writing unit 10, a processor 20, and a storage 30. The processor 20 can be a central processing unit (CPU). The storage 30 can be a read only memory (ROM), an erasable programmable read only memory (EPROM), or an electrically erasable programmable read only memory (EEPROM). In at least one embodiment, the electronic device can be, for example, a tablet computer, a smart phone, or other similar devices. FIG. 1 is only one example of the electronic device 100, it can include more or fewer components than those shown in the embodiment, or have a different configuration of the components.

The data writing unit 10 can include a plurality of programs in the form of one or more computerized instructions executed by the processor 20 to perform operations of the electronic device 100. In the embodiment, the data writing unit 10 includes a first detection module 11, a timing module 12, and a second detection module 13. In general, the word “module”, as used herein, refers to logic embodied in hardware or firmware, or to a collection of software instructions, written in a programming language, such as, Java, C, or assembly. One or more software instructions in the modules can be embedded in firmware, such as in an EPROM. The modules described herein can be implemented as either software and/or hardware modules and can be stored in any type of non-transitory computer-readable medium or other storage device. Some non-limiting examples of non-transitory computer-readable medium include CDs, DVDs, BLU-RAY, flash memory, and hard disk drives.

The first detection module 11 detects data transmission processes performed by the processor 20 to transmit data to the storage 30 in real-time. When a data transmission process is detected, the first detecting module 11 generates a timing command and a detection command.

The timing module 12 starts timing a time period duration of writing data into the storage 30 in response to the timing command.

The second detection unit 13 detects whether an Acknowledge (ACK) signal is sent from the storage 30 in response to the detection command. In this embodiment, the ACK signal indicates that the data has been successfully written into the storage 30 during the data transmission process. When the ACK signal is detected, the second detection unit 13 controls the timing module 12 to stop timing. If the ACK signal is not detected and the time period duration exceeds a predetermined time period (e.g., thirty seconds or one minute), the second detection unit 13 generates and outputs a control command to the processor 20, to control the processor 20 to restart data transmission process to re-transmit the data to the storage 30. In this embodiment, if the ACK has not been detected within the predetermined time period, it is regarded that malfunction (e.g., data error) happens during the process of writing the data into the storage 30. Then, the processor 20 is controlled to re-transmit the data to the storage 30 to eliminate the malfunction, thus system crash of the electronic device 100 can be avoided.

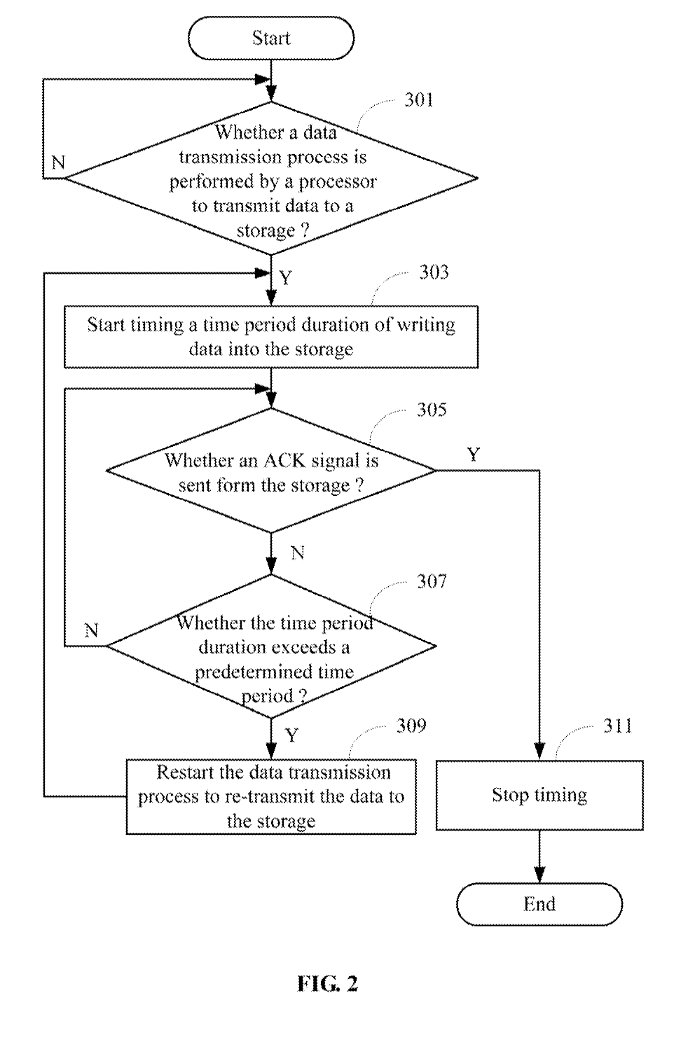

FIG. 2 is a flowchart of one embodiment of a data writing method implemented by the data writing unit of FIG. 1. Depending on the embodiment, additional steps can be added, other steps can be removed, and the ordering of the steps can be changed.

In 301, the first detection module detects whether a data transmission process is performed by the processor to transmit data to the storage. When a data transmission process is detected, 303 is implemented.

In 303, the timing module starts timing a time period duration of writing data into the storage.

In 305, the second detection unit detects whether an Acknowledge (ACK) signal is sent from the storage. In this embodiment, the ACK signal indicates that the data has been successfully written into the storage during the data transmission process. If the ACK signal sent from the storage is detected, 311 is implemented. If the ACK signal sent from the storage is not detected, 307 is implemented.

In 307, the timing module determines whether the time period duration exceeds a predetermined time period. If the time period duration exceeds the predetermined time period, 309 is implemented. Otherwise, 305 is repeated.

In 309, the second detection module generates and outputs a control command to the processor, to control the processor to restart the data transmission process to re-transmit the data to the storage, the procedure returns to 303.

In 311, the timing module stop timing, the procedure ends.

Although certain embodiments of the present disclosure have been specifically described, the present disclosure is not to be construed as being limited thereto. Various changes or modifications may be made to the present disclosure without departing from the scope thereof. The embodiments described herein are illustrative only, and are not intended to limit the scope of the following claims.

What is claimed is:

1. An electronic device, comprising:
a storage;
a processor; and
one or more programs executed by the processor to perform a data writing method, the data writing method comprising:
detecting data transmission processes performed by the processor to transmit data to the storage in real-time;
timing a time period duration of writing data into the storage, when a data transmission process performed by the processor to transmit data to the storage is detected;
detecting whether an Acknowledge (ACK) signal is sent from the storage, when the data transmission process is detected; and
controlling the processor to restart the data transmission process to re-transmit the data to the storage, when the ACK signal is not detected and the time period duration exceeds a predetermined time period.

2. The electronic device according to claim 1, wherein the ACK signal sent form the storage indicates that the data has been successfully written into the storage 30 during the data transmission process.

3. The electronic device according to claim 1, wherein the method further comprises:
stop timing when the ACK signal sent from the storage is detected

4. The electronic device according to claim 1, wherein the storage is a read only memory (ROM), an erasable programmable read only memory (EPROM), or an electrically erasable programmable read only memory (EEPROM).

5. A data writing method of an electronic device having a storage and a processor, comprising:
detecting data transmission processes performed by the processor to transmit data to the storage in real-time;
timing a time period duration of writing data into the storage, when a data transmission process performed by the processor to transmit data to the storage is detected;
detecting whether an Acknowledge (ACK) signal is sent from the storage when the data transmission process is detected; and
controlling the processor to restart the data transmission process to re-transmit the data to the storage, when the ACK signal is not detected and the time period duration exceeds a predetermined time period.

6. The method according to claim 1, wherein the ACK signal sent form the storage indicates that the data has been successfully written into the storage during the data transmission process.

7. The method according to claim 5, further comprising:
stop timing when the ACK signal sent from the storage is detected

8. The method according to claim 5, wherein the storage is a read only memory (ROM), an erasable programmable read only memory (EPROM), or an electrically erasable programmable read only memory (EEPROM).

9. A non-transitory storage medium having stored thereon instructions that, when executed by a processor of an electronic device, cause the processor to perform a data writing method to write data into a storage of the electronic device, the method comprising:
detecting data transmission processes performed by the processor to transmit data to the storage in real-time;
timing a time period duration of writing data into the storage, when a data transmission process performed by the processor to transmit data to the storage is detected;
detecting whether an Acknowledge (ACK) signal is sent from the storage when the data transmission process is detected; and
controlling the processor to restart the data transmission process to re-transmit the data to the storage, when the ACK signal is not detected and the time period duration exceeds a predetermined time period.

10. The non-transitory storage medium according to claim 9, wherein the ACK signal sent form the storage indicates that the data has been successfully written into the storage during the data transmission process.

11. The non-transitory storage medium according to claim 9, further comprising:
stop timing when the ACK signal sent from the storage is detected

12. The non-transitory storage medium according to claim 9, wherein the storage is a read only memory (ROM), an erasable programmable read only memory (EPROM), or an electrically erasable programmable read only memory (EEPROM).
